(19) United States
(12) Patent Application Publication
(10) Pub. No.: US 2024/0381595 A1
(43) Pub. Date: Nov. 14, 2024

(54) POWER ELECTRONICS COOLING LOOP FOR REFRIGERANT COMPRESSOR

(71) Applicant: DANFOSS A/S, NORDBORG (DK)

(72) Inventors: Myongsok SONG, Tallahassee, FL (US); Tianlei LI, Tallahassee, FL (US); Hunter KRAMER, Tallahassee, FL (US)

(21) Appl. No.: 18/692,961

(22) PCT Filed: Sep. 9, 2022
(86) PCT No.: PCT/US2022/043009

§ 371 Date: Mar. 18, 2024

Related U.S. Application Data
(60) Provisional application No. 63/245,466, filed on Sep. 17, 2021.

(51) Int. Cl. H05K 7/20; F25B 31/00

(52) U.S. Cl. CPC H05K 7/20936; H05K 7/20309; H05K 7/20318; H05K 7/20354; H05K 7/2039; F25B 31/008

(57) ABSTRACT

A refrigerant system according to an example of this disclosure includes a main refrigerant loop in communication with a condenser, an evaporator, and a compressor. A heat exchanger is arranged to cool electronic components. The heat exchanger has a cooling line, which is configured to receive refrigerant from the main refrigerant loop and a heat sink in communication with air surrounding the electronic components.

### CROSS-REFERENCED TO RELATED APPLICATION

This application is a 371 application of International Application No. PCT/US2022/043009, filed Sep. 9, 2022, which claims priority to U.S. Provisional Application No. 63/245,466, which was filed on Sep. 17, 2021.

### BACKGROUND

Refrigerant compressors are used to circulate refrigerant in a chiller or heat pump via a refrigerant loop. In addition to the compressor, refrigerant loops are known to include a condenser, an expansion device, and an evaporator. Some compressors provide cooling to the motor and/or associated power electronics by conveying refrigerant from the main loop to the motor and/or the power electronics.

### SUMMARY

A refrigerant system according to an example of this disclosure includes a main refrigerant loop in communication with a condenser, an evaporator, and a compressor. A heat exchanger is arranged to cool electronic components. The heat exchanger has a cooling line, which is configured to receive refrigerant from the main refrigerant loop and a heat sink in communication with air surrounding the electronic components.

In a further example of the foregoing, the heat sink has a plurality of fins in flow contact with the air.

In a further example of any of the foregoing, the plurality of fins have a louvered arrangement.

In a further example of any of the foregoing, the plurality of fins have a plurality of louvers. The plurality of fins have a fin height between 8 mm and 24 mm.

In a further example of any of the foregoing, the plurality of fins have a fin length between 70% and 100% of the fin height.

In a further example of any of the foregoing, the plurality of fins have a fin pitch between 10 and 30 fins per inch.

In a further example of any of the foregoing, the plurality of fins have a louver angle between 20 and 55 degrees.

In a further example of any of the foregoing, the plurality of fins have a distance between the plurality of louvers between 1 mm and 3 mm.

In a further example of any of the foregoing, the plurality of fins have a fin gage between 0.5 mm and 3 mm.

In a further example of any of the foregoing, the compressor is an oil-free centrifugal compressor.

In a further example of any of the foregoing, the refrigerant and the air to the

heat exchanger are actively controlled.

In a further example of any of the foregoing, the electronic components are at least one of insulated-gate bipolar transistors (IGBTs) and, softstart and silicon controlled rectifiers (SCRs).

In a further example of any of the foregoing, the heat exchanger includes a panel, a back plate with one or more channels. The heat sink is secured to the back plate.

In a further example of any of the foregoing, the heat sink is secured to the back plate via a cover and a plurality of fasteners. The cover includes a duct for flow of the air.

In a further example of any of the foregoing, the system is configured for liquid refrigerant to enter an expansion valve and then the heat exchanger via an inlet, which is connected to the front panel.

In a further example of any of the foregoing, the compressor is an oil-free centrifugal compressor. The heat exchanger includes a panel, a back plate with one or more channels. The heat sink is secured to the back plate. The heat sink is secured to the back plate via a cover and a plurality of fasteners. The cover includes a duct for flow of the air. The heat sink has a plurality of fins in flow contact with the air, and the plurality of fins have a louvered arrangement.

In a further example of any of the foregoing, the plurality of fins have a plurality of louvers. The plurality of fins have a fin height between 8 mm and 24 mm. The plurality of fins have a fin length between 70% and 100% of the fin height. The plurality of fins have a fin pitch between 10 and 30 fins per inch. The plurality of fins have a louver angle between 20 and 55 degrees. The plurality of fins have a distance between the plurality of louvers between 1 mm and 3 mm, and the plurality of fins have a fin gage between 0.5 mm and 3 mm.

In a further example of any of the foregoing, the heat exchanger includes a microchannel evaporator.

In a further example of any of the foregoing, the electronic components are at least one of insulated-gate bipolar transistors, softstart and silicon controlled rectifiers.

These and other features may be best understood from the following specification and drawings, the following of which is a brief description.

### BRIEF DESCRIPTION OF THE DRAWINGS

FIG. 1 schematically illustrates an example refrigerant loop.

FIG. 2 illustrates an example compressor.

FIG. 3 illustrates the example compressor with an example heat exchanger.

FIG. 4A illustrates an isometric view of the example heat exchanger.

FIG. 4B illustrates an exploded view of the example heat exchanger.

FIG. 4C illustrates an exploded view of the example heat exchanger.

FIG. 5A illustrates another example compressor with an example heat exchanger.

FIG. 5B illustrates an isometric view of the example heat exchanger.

FIG. 6A illustrates an example heat sink arrangement.

FIG. 6B illustrates another example heat sink arrangement.

FIG. 6C illustrates another example heat sink arrangement.

FIG. 6D illustrates another example heat sink arrangement.

FIG. 6E illustrates another example heat sink arrangement.

FIG. 6F illustrates another example heat sink arrangement.

FIG. 7A illustrates a side view of an example heat sink arrangement.

FIG. 7B illustrates a top view of an example heat sink arrangement.

FIG. 8A illustrates an example a thermal expansion valve.

FIG. 8B illustrates an example solenoid valve.

FIG. 8C illustrates an example electronic expansion valve.

FIG. 8D illustrates example capillary tubes.

FIG. 9A illustrates an example heat sink manufacturing method.

FIG. 9B illustrates another example heat sink manufacturing method.

FIG. 9C illustrates another example heat sink manufacturing method.

FIG. 9D illustrates another example heat sink manufacturing method.

FIG. 9E illustrates another example heat sink manufacturing method.

FIG. 9F illustrates another example heat sink manufacturing method.

FIG. 10A illustrates an example microchannel evaporator.

FIG. 10B illustrates the example microchannel evaporator.

FIG. 10C illustrates the example microchannel evaporator.

FIG. 10D illustrates the example microchannel evaporator and an example heat sink.

FIG. 11 illustrates another example microchannel evaporator.

### DETAILED DESCRIPTION

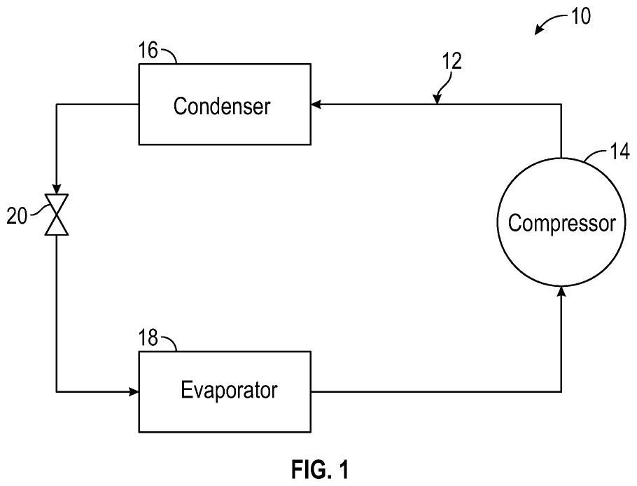

FIG. 1 schematically illustrates a refrigerant cooling system 10. The refrigerant system 10 includes a main refrigerant loop, or circuit, 12 in communication with a compressor or multiple compressors 14, a condenser 16, an evaporator 18, and an expansion device 20. This refrigerant system 10 may be used in a chiller or heat pump, for example. While a particular example of the refrigerant system 10 is shown, this disclosure extends to other refrigerant system configurations. For instance, the main refrigerant loop 12 can include an economizer downstream of the condenser 16 and upstream of the expansion device 20. The refrigerant cooling system 10 may be an air conditioning system, for example.

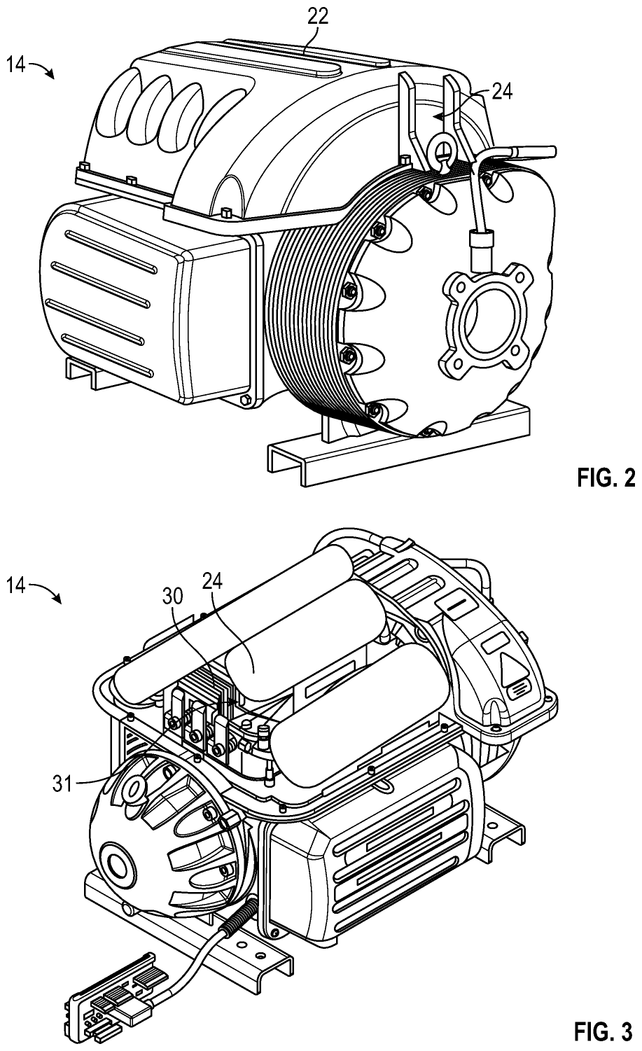

FIG. 2 illustrates an example compressor 14. The compressor 14 may be an oil-free centrifugal compressor, for example. The example compressor 14 may be a two-stage centrifugal compressor, including a first impeller upstream of a second impeller. Other multiple-stage compressors may be utilized in other embodiments. The impellers are driven by a motor. The impellers and motor are contained within a housing 22. Power electronics 24 are also arranged within the housing 22 and may include insulated-gate bipolar transistors (IGBTs) and silicon controlled rectifiers (SCRs), for example. The power electronics 24 may also include a DC-to-DC converter, snubbers, and/or capacitors among other possible electrical components.

Some known compressors rely on refrigerant to cool the power electronics, and the cooling path terminates into the evaporator or compressor suction. Heat is transferred away from the power electronics via refrigerant. However, in some cases, a high evaporator temperature is needed, e.g. higher than 20° C., which leads to a higher power electronics operating temperature. These higher power electronics operating temperatures may lead to safety and reliability issues. The heat exchanger arrangement examples shown and described herein adds an additional cooling loop to boost heat dissipation on the power electronics and prevent overheating of the electronics using a separate refrigeration cycle.

With reference to FIG. 3, and continuing reference to FIG. 2, the compressor 14 may be cooled using a cooling loop 31 having a heat exchanger 30. The example heat exchanger 30 uses a flow of refrigerant to cool the power electronics 24 via an additional refrigeration cycle. The refrigerant may be liquid refrigerant from a motor cooling channel or from the main refrigerant loop 12, for example.

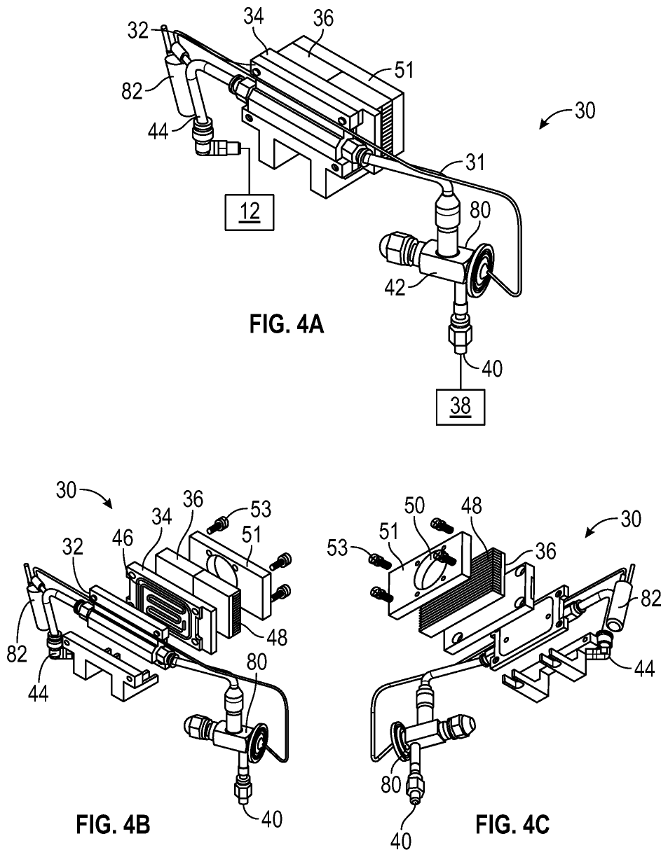

FIGS. 4A-4C illustrate an example heat exchanger 30. The cooling loop 31 with the heat exchanger 30 operates as an additional refrigeration cycle to remove heat from the power electronics. FIG. 4A shows an isometric view of the heat exchanger 30. The heat exchanger 30 generally includes a front panel 32, a back plate 34 and a heat sink 36. Liquid refrigerant from a source 38 enters an expansion valve first and then the heat exchanger 30 via an inlet 40 connected to the front panel 32. The source 38 may be a motor cooling channel or the main refrigerant loop 12, for example. The expansion valve 42 may be a thermal expansion valve 80, for example, or another type of valve, as explained further herein. After the expansion valve 42, the liquid refrigerant becomes two phase flow and experiences a drop in temperature. The refrigerant then flows through the front panel 32 and begins absorbing heat from the heat sink 36, which causes the refrigerant to evaporate and become vaporized. That is, the heat exchanger 30 operates as an evaporator. The refrigerant then exits back to the compressor 14 in the main refrigerant loop 12 via a back exit valve 44. The back exit valve 44 may dump the refrigerant from the cooling loop 31 at the compressor suction or evaporator 18, for example.

FIGS. 4B and 4C show exploded views of the heat exchanger 30. As shown in FIG. 4B, the back plate 34 has one or more channels 46. The cooling channel 46 may have a serpentine arrangement, for example. The arrangement of the channel 46 may be optimized to optimize the rate of heat transfer, for example. Refrigerant flows through these channels 46, and the channels 46 work as evaporators for the heat sink 36. The heat sink 36 has a plurality of fins 48. The heat sink 36 may be secured to the back plate 34 and front panel 32 via a cover 51 and a plurality of fasteners 53. Air from the housing 22 around the power electronics 24 flows through a duct 50 in the cover 51 to the fins 48 and heat transfers to the fins 48 via conduction. A mechanical support may be used to secure and support the heat exchanger 30 on the compressor 14. The inlet 40, heat exchanger 30, and exit valve 44 are considered together to define an example flow duct cooling line in this disclosure.

In some examples, the flow of refrigerant is actively controlled. A sensing element 82 may be arranged before the heat exchanger 30 to detect the refrigerant temperature at the outlet 40. The bulb 82 may then modulate the flow rate to maintain desired cooling. In other examples, passive cooling may be used. In this example, the expansion valve 42 is a fixed size expansion valve. The fixed size expansion valve may be between 0.05 mm and 0.5 mm, for example, depending on the application. In a further example, the expansion valve may be between 0.15 mm and 0.35 mm. In some examples, the air flow through the duct 50 may also be actively controlled. In this example, a fan is arranged within the housing 22 and is operated to increase or decrease air flow through the duct 50 to maintain desired cooling.

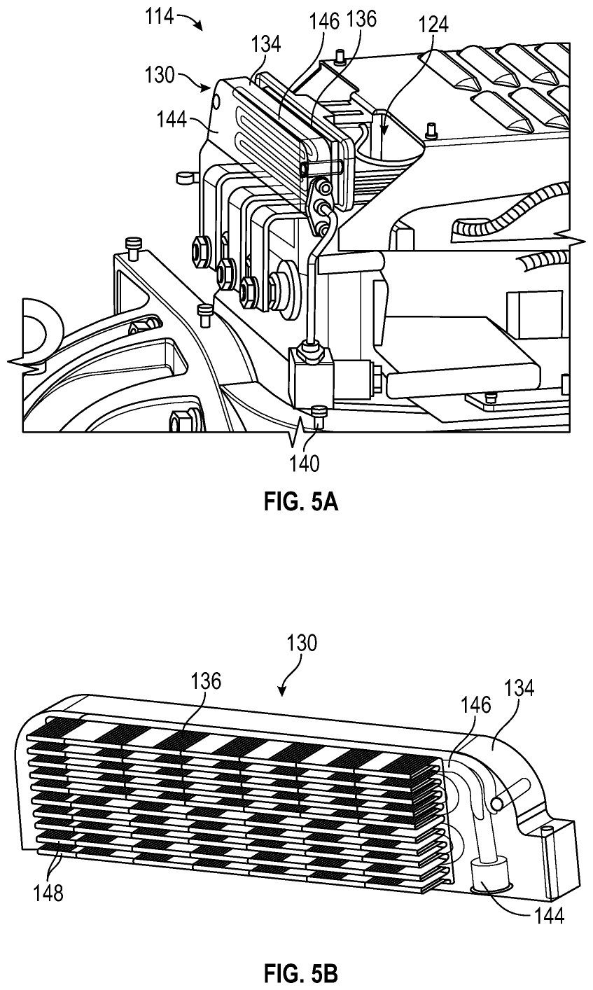

FIG. 5A illustrates another example compressor 114 having a heat exchanger 130. To the extent not otherwise described or shown, the compressor 114 corresponds to the compressor 14 of FIGS. 4A-4C, with like parts having reference numerals preappended with a “1.” In this example, the heat exchanger 130 is sized and shaped to fit on an upper portion of the compressor 114 within the housing (shown in FIG. 2).

FIG. 5B illustrates the example heat exchanger 130. In this example, the back plate 134 has a channel 146 for refrigerant flow. As can be seen in this example, the cooling channel 146 has a serpentine arrangement that flows from an inlet 140 to an outlet 144. The rate of heat transfer (\dot{Q}) is defined as a product of the heat transfer area (A), a correction area for more complex heat exchangers (F), the overall heat transfer coefficient based on area and log mean temperature difference (U), and the log mean temperature difference (ΔT ₗₘ). The cooling channel 146 is designed to optimize the contact area of the refrigerant and the mass flow rate of the refrigerant.

The heat sink 136 has a plurality of fins 148 that are in flow contact with the air. In this example, the plurality of fins 148 are arranged in a louvered pattern. Although an example fin pattern is shown, other heat sink arrangements may be used, as further shown and described herein.

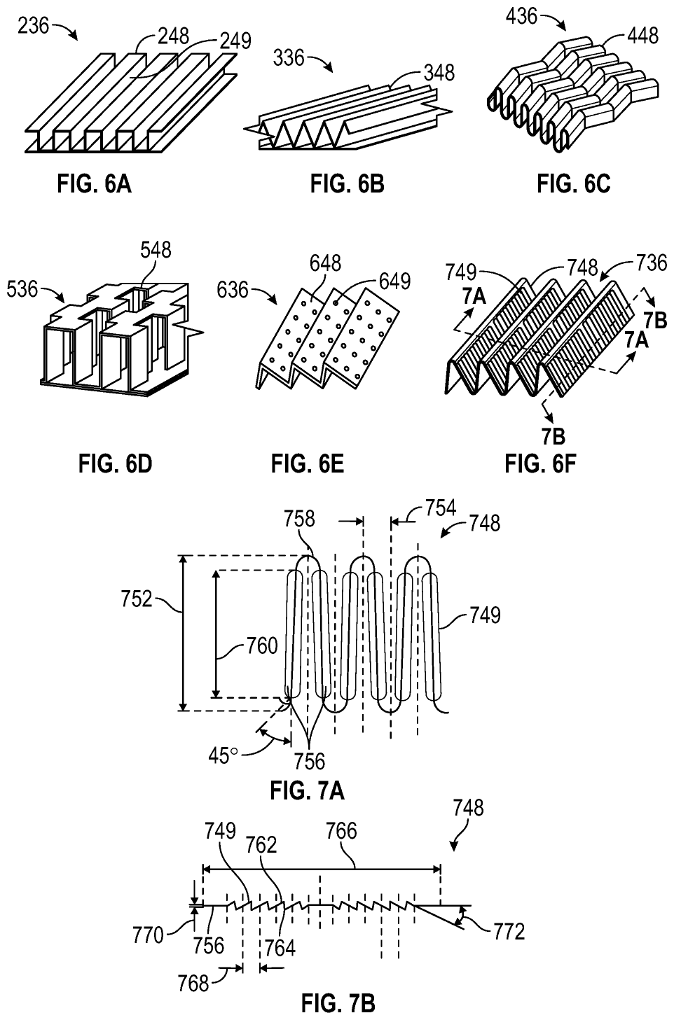

FIGS. 6A to 6F illustrate example heat sink fin arrangements. The heat sink 136 may have a variety of geometries. FIG. 6A illustrates a heat sink 236 having a plurality of fins 248 in a rectangular arrangement. In this example, the plurality of fins 248 have a rectangular shape and a plurality of holes 249 extend through the fins 248 for cooling. FIG. 6B illustrates another example heat sink 336 having a plurality of fins 348 in a triangular arrangement. FIG. 6C illustrates another example heat sink 436 having a plurality of fins 448 in a wavy arrangement. FIG. 6D illustrates another example heat sink 536 having a plurality of fins 548 in an offset strip arrangement. FIG. 6E illustrates another example heat sink 636 having a plurality of fins 648 with a plurality of perforations 649. FIG. 6F illustrates another example heat sink 736 having a plurality of fins 748 with a plurality of louvers 749. The design and geometry of the heat sink may be selected based on cooling performance, complexity, and cost for a particular compressor application.

FIGS. 7A and 7B illustrate further details of a louvered heat sink arrangement. FIG. 7A shows a side view of the louvered heat sink 736. The fins 748 are arranged in in a wavy pattern. The fins 748 have a height 752 that may be between about 8 mm to about 24 mm, for example. The fins 748 have a fin pitch 754 that may be between about 10 to 30 fins per inch. The fins 748 have a plurality of walls 756 that extend substantially vertically between bends 758. In this disclosure, substantially vertical means having a vector component in a vertical direction relative to a base of the heat sink that is greater than a vector component in a horizontal direction. A plurality of louvers 749 extend from the walls 756. The louvers 749 may be corrugations that are formed by cutting and bending a portion of the walls 756 to form a vane 762 and an opening 764 (shown in FIG. 7B). The louvers 749 have a length 760. The length 760 may be between 70% and 100% of the fin height 752, for example.

FIG. 7B shows a top view of the louvered heat sink 736. The fin 748 has a width 766 taken in a direction that is substantially perpendicular to the fin height 752. The louvers 749 along the fin 748 are spaced by a pitch 768. The louver pitch 768 may be between 1 and 3 mm, for example. The fin gage 770 may be between 0.5 and 3 mm, for example. The louvers 749 have an angle 772 relative to the wall 756. The angle 772 may be between 20° and 55°. This louvered fin design may be particularly beneficial in the example oil-free centrifugal compressor heat exchanger design.

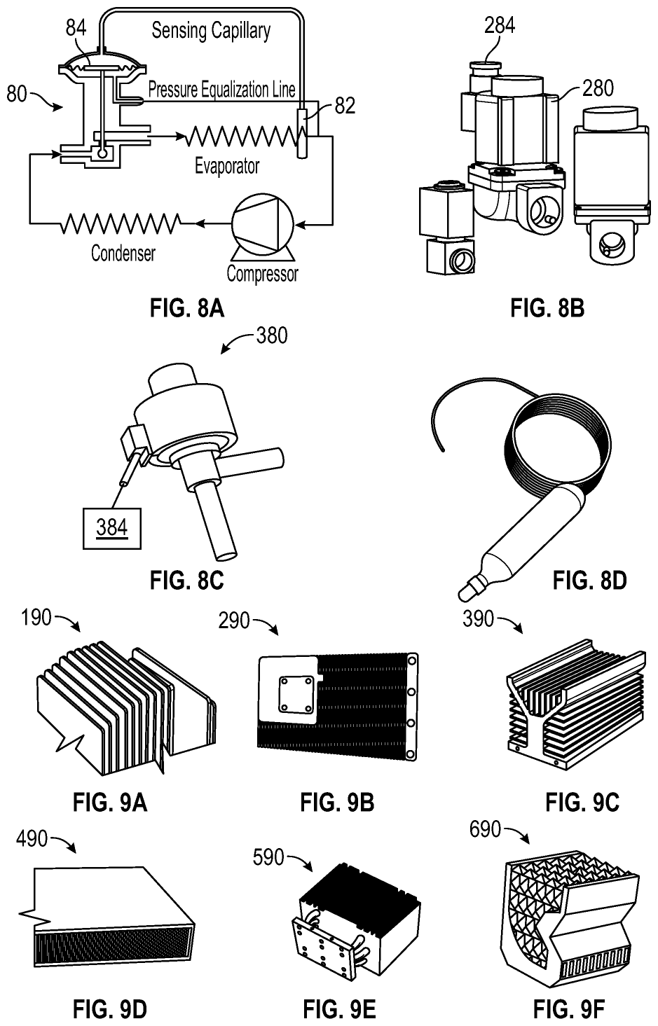

The flow control of refrigerant may be controlled to maintain cooling performance. FIGS. 8A-8D illustrate example components for active flow control. FIG. 8A illustrates a thermal expansion valve (TEV) 80, which may be used to control the flow of refrigerant. The thermal expansion valve 80 regulates the refrigerant that flows out of the heat exchanger 30 by a sensing bulb 82 from the heat exchanger output temperature. A thermal expansion valve 80 provides a cost-efficient design. The valve 80 may be selectively opened and closed in response to instructions from a controller 84. The controller 84, illustrated schematically, may be programmed with executable instructions for interfacing with and operating the various components of the compressor 14. The controller 84 is configured to receive information from the compressor 14 and is configured to interpret that information and issue commands to various components of the compressor 14. The controller 84 may include hardware and software. Further, the controller 84 may additionally include a processing unit and non-transitory memory for executing the various control strategies and modes of the compressor 14.

FIG. 8B shows a solenoid valve 280, which may be used to control the refrigerant in another example. A solenoid valve 280 may control the flow by external sensors and processors to drive performance in a non-uniform mass flow system. A solenoid valve 280 may also require a smaller space to optimize the size of the compressor. FIG. 8C shows an electronic expansion valve (EEV) 380, which may be used to control the refrigerant in another example. An EEV 380 contains a small microprocessor that reads in data from a temperature sensor to determine how much flow to allow through. An EEV 380 works very efficiently, but may have a higher cost due to the added complexity.

FIG. 8D shows capillary tubes 480, which may be used to control the refrigerant in another example. Capillary tubes 480 operate by creating a fixed pressure differential between the two sides via small tubes. The tubes may have a diameter between about 0.5 mm and 1.0 mm, for example. Capillary tubes 480 are very simple, as they are a fixed size and have no moving parts, which results in little wear and maintenance. However, capillary tubes 480 require a fixed amount of refrigerant and provide a constant pressure difference.

The particular flow control method may be selected based on the particular needs of the system, such as efficiency, space, and cost. Although example flow control methods are shown and described, other flow control methods may be used. Further, although the flow control is described with respect to the refrigerant, the air across the heat sink may also be actively controlled. For example, a fan may be arranged inside of the housing 22. The fan may be used to pull air within the housing 22 across the heat sink 36. Active cooling control of the refrigerant and/or air may improve the overall cooling performance of the heat exchanger 30.

The heat sink 36 may be manufactured by one or more of several manufacturing processes, as shown in FIGS. 9A to 9F. The heat sink 36 may be made via a machining process 190, in one example. Machining is suitable for a one-piece design, for example. The heat sink 36 may be formed via a die casting process 290, which may provide a complex design for a relatively low price. The heat sink 36 may be formed via an extrusion process 390, which allows for formation of certain fin geometries. The heat sink 36 may be formed with a friction stir welding process 490, which may connect heat sinks 36 seamlessly to enable complex surfaces in the design. The heat sink 36 may be formed via a brazing process 590 for assembling fins 48. The heat sink 36 may be formed via a 3-D printing process 690, which may provide complex geometry. The heat sink 36 may be formed with a forging process, in some examples. Further, the heat sink 36 may be formed with a combination of the above processes. The manufacturing method may depend on the particular heat sink design.

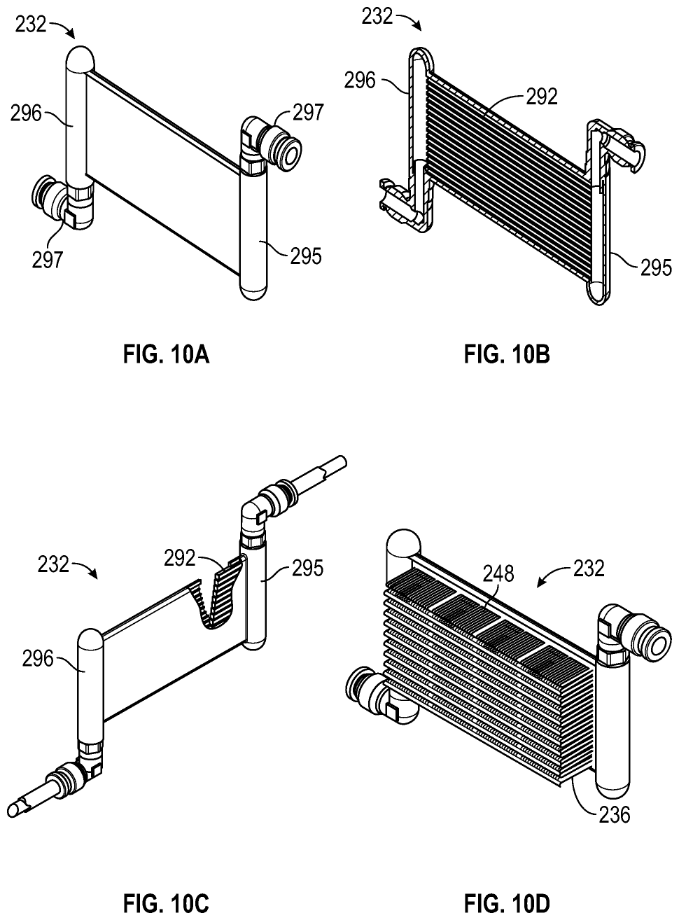

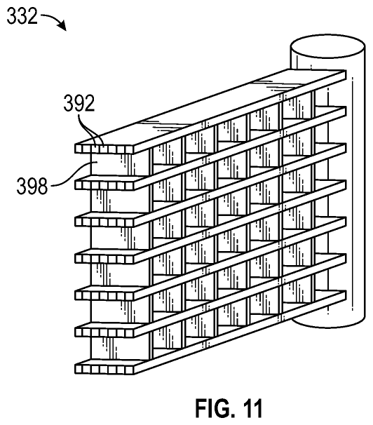

An example heat exchanger is substantially similar to the heat exchangers, 130 except that the front panel 32 and back plate 34 are replaced with the microchannel evaporator 232 shown in FIGS. 10A-10C. The example microchannel evaporator 232 includes a plurality of microchannels 292 connected at their respective ends by inlet and outlet headers 295 and 296, respectively. The microchannel plate may be welded or brazed to the inlet and exit distribution headers 295, 296 and the headers 295, 296 may be equipped with connection fittings 297, such as o-ring, threaded, brazed, or welded fittings in some examples. In some examples, as shown in FIG. 10D, a heat sink 236 having a plurality of fins 248 may be placed at a face of the microchannel evaporator 232. The heat sink may be configured similarly to the heat sinks 36, 136 disclosed herein in some examples. Although one row of microchannels extending along the headers 295, 286 is shown in the example, other microchannel configurations are contemplated. In another example microchannel evaporator 332, as shown in FIG. 11, multiple rows of microchannels 394 may be utilized and may include a plurality of fins 398 therebetween.

An optimized heat sink design may enhance cooling performance in an active cooling system. The disclosed heat exchanger design circulates air to absorb heat generated from power electronics via convection. The heat energy in the air is then transferred to the refrigerant flowing through the heat exchanger. This arrangement permits effective cooling of the power electronics, which allows the compressor to be used in a broader range of applications that may have been previously limited by the ambient temperature. This arrangement also has a very small package, allowing the heat exchanger to fit within the compressor housing 22.

It should be understood that directional terms such as “upper” and “top” are used above with reference to the normal operational attitude of the compressor 14 relative to a surface upon which the compressor 14 is mounted (i.e., a ground or floor surface). Further, these terms have been used herein for purposes of explanation, and should not be considered otherwise limiting. Terms such as “generally,” “substantially,” and “about” are not intended to be boundaryless terms, and should be interpreted consistent with the way one skilled in the art would interpret those terms.

It should be understood that although a particular component arrangement is disclosed and illustrated in these exemplary embodiments, other arrangements could also benefit from the teachings of this disclosure.

Although the different examples have the specific components shown in the illustrations, embodiments of this disclosure are not limited to those particular combinations. It is possible to use some of the components or features from one of the examples in combination with features or components from another one of the examples. In addition, the various figures accompanying this disclosure are not necessarily to scale, and some features may be exaggerated or minimized to show certain details of a particular component or arrangement.

One of ordinary skill in this art would understand that the above-described embodiments are exemplary and non-limiting. That is, modifications of this disclosure would come within the scope of the claims. Accordingly, the following claims should be studied to determine their true scope and content.

1. A refrigerant system, comprising:
a main refrigerant loop in communication with a condenser, an evaporator, and a compressor; and
a heat exchanger arranged to cool electronic components, the heat exchanger having a cooling line configured to receive refrigerant from the main refrigerant loop and a heat sink in communication with air surrounding the electronic components.

2. The system as recited in claim 1, wherein the heat sink has a plurality of fins in flow contact with the air.

3. The system as recited in claim 2, wherein the plurality of fins have a louvered arrangement.

4. The system as recited in claim 3, wherein the plurality of fins having a plurality of louvers, the plurality of fins having a fin height between 8 mm and 24 mm.

5. The system as recited in claim 4, wherein the plurality of fins have a fin length between 70% and 100% of the fin height.

6. The system as recited in claim 4, wherein the plurality of fins have a fin pitch between 10 and 30 fins per inch.

7. The system as recited in claim 6, wherein the plurality of fins have a louver angle between 20 and 55 degrees.

8. The system as recited in claim 7, wherein the plurality of fins have a distance between the plurality of louvers between 1 mm and 3 mm.

9. The system as recited in claim 7, wherein the plurality of fins have a fin gage between 0.5 mm and 3 mm.

10. The system as recited in claim 1, wherein the compressor is an oil-free centrifugal compressor.

11. The system as recited in claim 1, wherein the refrigerant and the air to the heat exchanger are actively controlled.

12. The system as recited in claim 1, wherein the electronic components are at least one of insulated-gate bipolar transistors (IGBTs) and silicon controlled rectifiers (SCRs).

13. The system as recited in claim 1, wherein the heat exchanger includes a panel, a back plate with one or more channels, wherein the heat sink is secured to the back plate.

14. The system as recited in claim 13, wherein the heat sink is secured to the back plate via a cover and a plurality of fasteners, the cover including a duct for flow of the air.

15. The system as recited in claim 14, wherein the system is configured for liquid refrigerant to enter an expansion valve and then the heat exchanger via an inlet connected to the front panel.

16. The system as recited in claim 1, wherein the compressor is an oil-free centrifugal compressor, the heat exchanger includes a panel, a back plate with one or more channels, wherein the heat sink is secured to the back plate, the heat sink is secured to the back plate via a cover and a plurality of fasteners, the cover including a duct for flow of the air, the heat sink has a plurality of fins in flow contact with the air, and the plurality of fins have a louvered arrangement.

17. The system as recited in claim 16, wherein the plurality of fins having a plurality of louvers, the plurality of fins having a fin height between 8 mm and 24 mm, the plurality of fins have a fin length between 70% and 100% of the fin height, the plurality of fins have a fin pitch between 10 and 30 fins per inch, the plurality of fins have a louver angle between 20 and 55 degrees, the plurality of fins have a distance between the plurality of louvers between 1 mm and 3 mm, and the plurality of fins have a fin gage between 0.5 mm and 3 mm.

18. The system as recited in claim 1, wherein the heat exchanger includes a microchannel evaporator.

19. The system as recited in claim 18, wherein the electronic components are at least one of insulated-gate bipolar transistors and silicon controlled rectifiers.
